(19) United States
(12) Patent Application Publication
(10) Pub. No.: US 2015/0137342 A1
(43) Pub. Date: May 21, 2015

(54) INDUCTOR/TRANSFORMER OUTSIDE OF SILICON WAFER

(71) Applicant: Marvell World Trade Ltd., St. Michael (BB)

(72) Inventor: Sehat Sutardja, Los Altos Hills, CA (US)

(21) Appl. No.: 14/547,177

(22) Filed: Nov. 19, 2014

Related U.S. Application Data
(60) Provisional application No. 61/906,692, filed on Nov. 20, 2013.

(51) Int. Cl. H01L 23/498; H01L 23/64; H01L 23/532

(52) U.S. Cl. CPC H01L 23/49827; H01L 23/53228; H01L 23/645
USPC 257/692; 438/125

(57) ABSTRACT

An integrated circuit package includes an integrated circuit and an interposer layer. The interposer layer is arranged above the integrated circuit and includes an inductor formed at least partially within the interposer layer. The inductor includes a first pair of conductive pillars including a first conductive pillar and a second conductive pillar formed within a first via and a second via, respectively. The first via and the second via are formed through the interposer layer. The inductor further includes a first conductive trace connected across first ends of the first conductive pillar and the second conductive pillar on a first surface of the interposer layer, and a first conductive interconnect structure connected between second ends of the first conductive pillar and the second conductive pillar and the integrated circuit.

### CROSS-REFERENCE TO RELATED APPLICATIONS

This application claims the benefit of U.S. Provisional Application No. 61/906,692, filed on Nov. 20, 2013. The entire disclosure of the application referenced above is incorporated herein by reference.

### FIELD

The present disclosure relates to systems and methods for providing inductor structures external to an integrated circuit.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

A printed circuit board (such as a micro printed circuit board) typically includes one or more integrated circuits (e.g., silicon chips/wafers) arranged on the printed circuit board. The integrated circuits may be connected to the printed circuit board via solder bumps and/or other interconnect structures. Example integrated circuits include readout chips (e.g., for chip-to-chip interconnect) and/or other radio frequency (RF) chips.

### SUMMARY

An integrated circuit package includes an integrated circuit and an interposer layer. The interposer layer is arranged above the integrated circuit and includes an inductor formed at least partially within the interposer layer. The inductor includes a first pair of conductive pillars including a first conductive pillar and a second conductive pillar formed within a first via and a second via, respectively. The first via and the second via are formed through the interposer layer. The inductor further includes a first conductive trace connected across first ends of the first conductive pillar and the second conductive pillar on a first surface of the interposer layer, and a first conductive interconnect structure connected between second ends of the first conductive pillar and the second conductive pillar and the integrated circuit.

A method of forming an integrated circuit package includes forming an interposer layer above an integrated circuit and forming an inductor at least partially within the interposer layer. Forming the inductor includes forming a first via and a second via through the interposer layer, forming a first pair of conductive pillars, including a first conductive pillar and a second conductive pillar, within the first via and the second via, respectively, connecting a first conductive trace connected across first ends of the first conductive pillar and the second conductive pillar on a first surface of the interposer layer, and connecting a first conductive interconnect structure between second ends of the first conductive pillar and the second conductive pillar and the integrated circuit.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF DRAWINGS

FIG. 1 is an example integrated circuit package including an interposer layer according to the principles of the present disclosure.

FIG. 2 is an example an example integrated circuit package including an interposer layer shown in more detail according to the principles of the present disclosure.

FIG. 3 is an example single turn inductor according to the principles of the present disclosure.

FIG. 4 is an example multi-turn inductor according to the principles of the present disclosure.

FIG. 5 is an example interposer layer including a plurality of inductors according to the principles of the present disclosure.

FIG. 6 is a top-down view of the example interposer layer shown in FIG. 5 according to the principles of the present disclosure.

FIG. 7 is an example integrated circuit including one or more inductors formed directly on the surface of the integrated circuit according to the principles of the present disclosure.

FIG. 8 is an example FinFET wafer including one or more inductors according to the principles of the present disclosure.

In the drawings, reference numbers may be reused to identify similar and/or identical elements.

### DESCRIPTION

In some integrated circuits (e.g., silicon chips/wafers, systems on a chip, etc.), including, but not limited to, readout chips and radio frequency (RF) chips, it may be difficult to form inductors having a desired Q (quality) factor within the silicon of the chip. Accordingly, in some implementations, inductors are arranged external to the integrated circuit and may be connected to the integrated circuit via bond wires or other interconnect structures. However, externally connected inductors may not provide accurate performance.

An integrated circuit package according to the principles of the present disclosure may include one or more vertically-stacked integrated circuits (e.g., silicon wafers/chips, systems on a chip, etc.), which in turn may be arranged on a printed circuit board (PCB) or other package substrate. The package includes an interposer layer, formed of glass, silicon dioxide, or another suitable material, arranged, for example, adjacent to a chip, between two chips, and/or between a chip and a PCB. A pair of vias are formed vertically through the interposer layer and filled with a conductive plug (e.g., a copper plug or pillar). A conductive trace formed on a surface of the interposer layer connects respective first ends of the copper pillars together, and respective second ends of the copper pillars are connected to a surface of an adjacent structure (e.g., an adjacent chip, PCB, or package substrate). For example, the second ends of the copper pillars may be connected to the surface of the adjacent structure using solder bumps or another suitable interconnect structure.

Accordingly, the copper pillars and conductive trace form a single turn inductor perpendicular to a surface of the adjacent structure. Additional inductor turns can be formed using additional pairs of vias and copper pillars connected to the first inductor turn using conductive traces formed on another surface of the interposer layer and/or on a surface of the adjacent structure. An inductance value of the inductor may be determined by, for example, a number of turns formed in the interposer layer, a height of the solder bumps, and/or a height of the copper pillars (e.g., as defined by a thickness of the interposer layer). For example only, the thickness of the interposer layer may be between 100 μm and 250 μm.

In this manner, one or more inductors, transformers (such as interleaved RF output transformers), etc. can be provided in the interposer layer without using space within the silicon wafer or chip. The inductors can be formed to have a desired high Q factor and inductance values. Further, a pitch and diameter of the copper pillars in the interposer layer can be varied as desired. For example, a relatively high pitch (e.g., less than 100 μm, as low as 50 μm or less, with a pillar diameter of less than 50 μm) may be used to form multiple high Q factor, multi-turn inductors within a single interposer layer to be integrated with a relatively large system on a chip (SOC). Capacitance between inductors formed in the interposer layer can be controlled according to a distance between the inductors. Accordingly, a very low capacitance, and therefore improved high frequency performance, can be achieved by increasing the distance between the inductors as desired. Further, a portion of a magnetic field associated with the inductor that intersects the silicon wafer or chip is significantly reduced.

In other implementations, single turn inductors may be formed directly on a surface of a chip or wafer without the use of an interposer layer. For example, a pair of solder bumps and/or copper pillars may be formed directly on the surface of the chip. A conductive trace formed on the surface of the chip connects the copper pillars together to form the inductor.

The principles of the present disclosure may also be implemented with FinFET wafers. For example, a glass substrate having a temperature expansion coefficient approximately equal to that of a silicon wafer may be formed on (e.g., bonded to) a surface of a FinFET wafer. The copper pillars may be formed (e.g., with a pitch of 50 μm or less, which corresponds to approximately 20 μm between adjacent copper pillars) within the glass substrate as described above to provide one or more inductors connected to the FinFET wafer. Accordingly, inductors can be provided without using any significant area of the silicon wafer. A highly efficient power combiner RF output transformer with an extremely low coupling capacitance can be constructed in a similar manner.

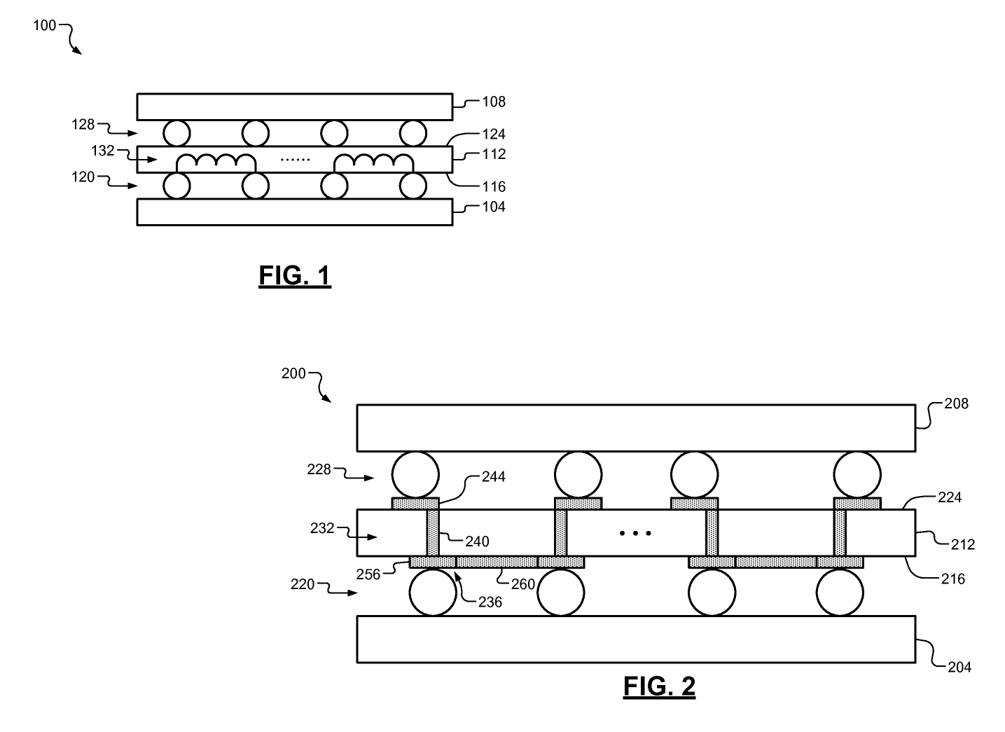

FIG. 1 shows an example integrated circuit package 100 according to the principles of the present disclosure. The integrated circuit package 100 includes, for example, an integrated circuit 104 (e.g., corresponding to a silicon chip or wafer), an integrated circuit 108, and an interposer layer 112. Integrated circuits 104 and 108 may include, for example only, SOCs. The interposer layer 112 may be formed from glass, silicon dioxide, or any other suitable material. Although not shown, integrated circuit package 100 may be arranged on a PCB or other substrate.

The integrated circuit 104 is connected to a first surface 116 of the interposer layer 112 using an interconnect structure such as, for example only, solder bumps 120. Similarly, the integrated circuit 108 is connected to a second surface 124 of the interposer layer 112 using solder bumps 128. The interposer layer 112 includes one or more inductors 132, shown schematically, formed within the interposer layer 112. Although shown with multiple turns, the inductors 132 may include one or more turns. Each of the inductors 132 may include a same number of turns or a different number of turns.

FIG. 2 shows an example integrated circuit package 200 according to the principles of the present disclosure. For example, the integrated circuit package 200 corresponds to the integrated circuit package 100 of FIG. 1 shown in more detail. The integrated circuit package 200 includes, for example, an integrated circuit 204, an integrated circuit 208, and an interposer layer 212.

The integrated circuit 204 is connected to a first surface 216 of the interposer layer 212 using an interconnect structure such as, for example only, solder bumps 220. Similarly, the integrated circuit 208 is connected to a second surface 224 of the interposer layer 212 using solder bumps 228. The interposer layer 212 includes one or more inductors 232, shown in cross-section, formed within the interposer layer 212. Although shown with multiple turns, the inductors 232 may include one or more turns.

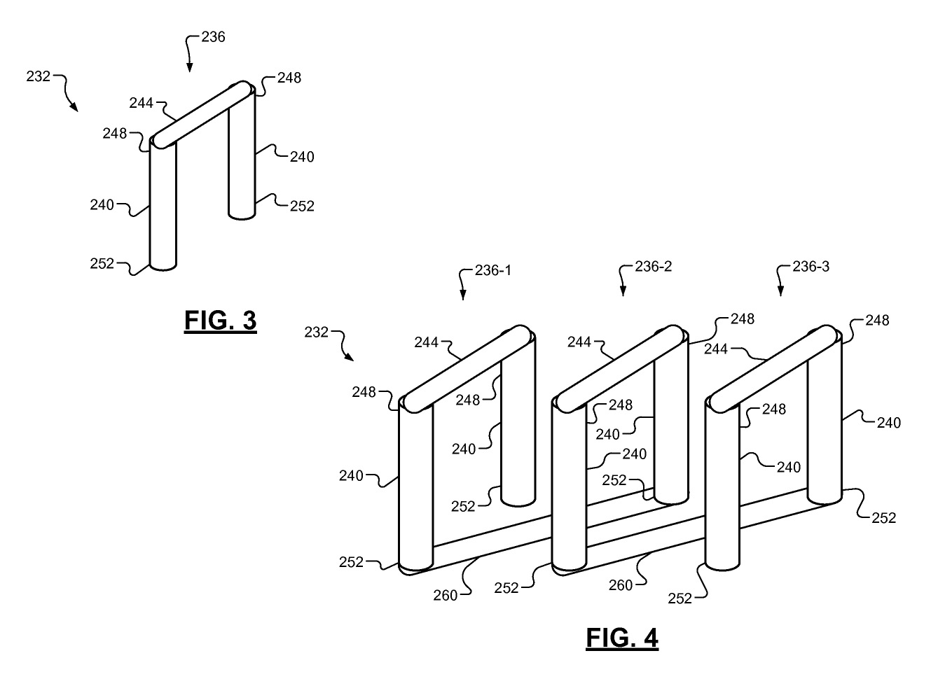

Each of the inductors 232 includes one or more turns 236. For example, FIG. 3 shows an example one of the inductors 232 having a single turn 236. Each of the turns 236 of the inductor 232 includes a pair of conductive (e.g., copper) pillars 240 formed (e.g., deposited) within the interposer layer 212. For example, vias (i.e., holes) may be formed (e.g., laser drilled) in the interposer layer 212. The vias are filled with copper or another suitable conductive material to form the conductive plugs or pillars 240. A conductive trace 244 connects first ends 248 of the pillars 240 on the second surface 224 of the interposer layer 212 to form the turn 236 of the inductor 232. Second ends 252 of the conductive pillars 240 are connected to the solder bumps 220 using, for example only, conductive pads 256.

An inductance L of the inductor 232 corresponds to, for example, L=AN², where A corresponds to an area of the inductor 232 and N corresponds to a number of turns of the inductor 232. As shown in FIG. 3, the area A corresponds to a product of a height of the pillars 240 (i.e., a thickness of the interposer layer 212) and a spacing between the pillars 240.

FIG. 4 shows an example one of the inductors 232 having multiple turns 236-1, 236-2, and 236-3, referred to collectively as the turns 236. To form the inductor 232 having the multiple turns 236 as shown in FIG. 4, a conductive trace 260 connects a second end 252 of a pillar 240 in a first one of the turns 236-1 to a second end 252 of a pillar 240 in a second one of the turns 236-2. The conductive trace 260 may be formed on the first surface 216 of the interposer layer 212.

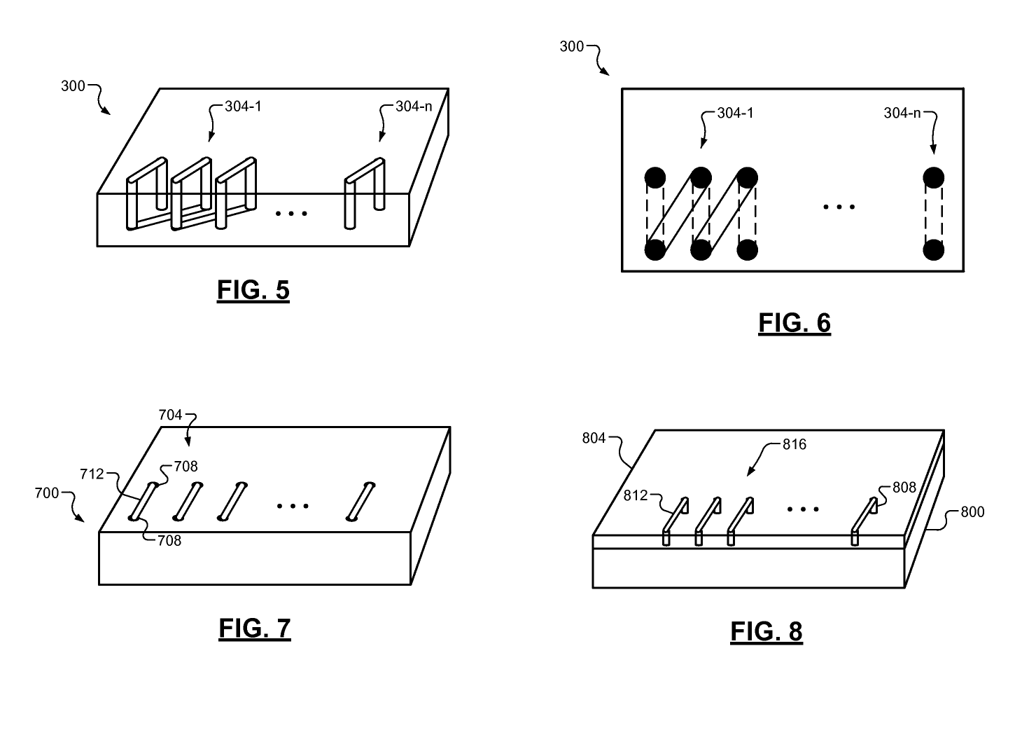

FIG. 5 shows an example interposer layer 300 including a plurality of inductors 304-1 . . . 304-n, referred to collectively as inductors 304. For example only, the inductor 304-1 is shown as a multi-turn inductor while the inductor 304-n is shown as a single turn inductor. FIG. 6 shows a top-down view of the example interposer layer 300 of FIG. 5.

FIG. 7 shows an example integrated circuit 700 according to another implementation of the principles of the present disclosure. One or more single turn inductors 704 may be formed directly on a surface of the integrated circuit 700 without the use of an interposer layer. For example, a pair of solder bumps and/or copper pillars 708 may be formed directly on the surface of the integrated circuit 700. A conductive trace 712 formed on the surface of the integrated circuit 700 connects the copper pillars 708 together to form the inductor 704.

FIG. 8 shows a FinFET wafer 800 according to the principles of the present disclosure. A glass substrate 804 having a temperature expansion coefficient approximately equal to that of a silicon wafer may be formed on (e.g., bonded to) a surface of a FinFET wafer. Conductive (e.g., copper) pillars 808 may be formed within the glass substrate 804 and connected with respective conductive traces 812 (e.g., as described above in FIG. 2) to provide one or more inductors 816 connected to the FinFET wafer 800.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A or B or C), using a non-exclusive logical OR. It should be understood that one or more steps within a method may be executed in different order (or concurrently) without altering the principles of the present disclosure.

What is claimed is:

1. An integrated circuit package, comprising:
an integrated circuit; and
an interposer layer arranged above the integrated circuit, the interposer layer including an inductor formed at least partially within the interposer layer, the inductor comprising
a first pair of conductive pillars including a first conductive pillar and a second conductive pillar formed within a first via and a second via, respectively, wherein the first via and the second via are formed through the interposer layer,
a first conductive trace connected across first ends of the first conductive pillar and the second conductive pillar on a first surface of the interposer layer, and
a first conductive interconnect structure connected between (i) second ends of the first conductive pillar and the second conductive pillar and (ii) the integrated circuit.

2. The integrated circuit package of claim 1, wherein at least one of the first conductive trace and the first pair of conductive pillars comprises copper.

3. The integrated circuit package of claim 1, wherein the interposer layer comprises at least one of glass and silicon dioxide.

4. The integrated circuit package of claim 1, wherein the interposer layer is connected to the integrated circuit using a plurality of solder bumps arranged between a second surface of the interposer layer and the integrated circuit.

5. The integrated circuit package of claim 4, wherein the first interconnect structure includes the solder bumps.

6. The integrated circuit package of claim 1, wherein the inductor further comprises:
a second pair of conductive pillars including a third conductive pillar and a fourth conductive pillar formed within a third via and a fourth via, respectively, wherein the third via and the fourth via are formed through the interposer layer,
a second conductive trace connected across first ends of the third conductive pillar and the fourth conductive pillar on the first surface of the interposer layer,
a second conductive interconnect structure connected between (i) second ends of the third conductive pillar and the fourth conductive pillar and (ii) the integrated circuit, and
a third conductive trace connected across the second end of the second conductive pillar and the second end of the third conductive pillar on a second surface of the interposer layer.

7. The integrated circuit package of claim 1, wherein the first conductive pillar and the second conductive pillar are perpendicular to a first surface of the integrated circuit.

8. The integrated circuit package of claim 1, wherein the interposer layer includes a plurality of the inductors.

9. The integrated circuit package of claim 1, wherein the first pair of conductive pillars and the first conductive trace correspond to one turn of the inductor.

10. A method of forming an integrated circuit package, the method comprising:
forming an interposer layer above an integrated circuit;
forming an inductor at least partially within the interposer layer, wherein forming the inductor comprises
forming a first via and a second via through the interposer layer,
forming a first pair of conductive pillars, including a first conductive pillar and a second conductive pillar, within the first via and the second via, respectively,
connecting a first conductive trace connected across first ends of the first conductive pillar and the second conductive pillar on a first surface of the interposer layer, and
connecting a first conductive interconnect structure between (i) second ends of the first conductive pillar and the second conductive pillar and (ii) the integrated circuit.

11. The method of claim 10, wherein at least one of the first conductive trace and the first pair of conductive pillars comprises copper.

12. The method of claim 10, wherein the interposer layer comprises at least one of glass and silicon dioxide.

13. The method of claim 10, further comprising connecting the interposer layer to the integrated circuit using a plurality of solder bumps arranged between a second surface of the interposer layer and the integrated circuit.

14. The method of claim 13, wherein the first interconnect structure includes the solder bumps.

15. The method of claim 10, wherein forming the inductor further comprises:
forming a third via and a fourth via through the interposer layer;
forming a second pair of conductive pillars including a third conductive pillar and a fourth conductive pillar within the third via and the fourth via, respectively;
connecting a second conductive trace across first ends of the third conductive pillar and the fourth conductive pillar on the first surface of the interposer layer;
connecting a second conductive interconnect structure between (i) second ends of the third conductive pillar and the fourth conductive pillar and (ii) the integrated circuit; and
connecting a third conductive trace across the second end of the second conductive pillar and the second end of the third conductive pillar on a second surface of the interposer layer.

16. The method of claim 10, wherein the first conductive pillar and the second conductive pillar are perpendicular to a first surface of the integrated circuit.

17. The method of claim 10, wherein the interposer layer includes a plurality of the inductors.

18. The method of claim 10, wherein the first pair of conductive pillars and the first conductive trace correspond to one turn of the inductor.
